(19) United States
(12) Patent Application Publication
(10) Pub. No.: US 2025/0113686 A1
(43) Pub. Date: Apr. 3, 2025

(54) LIGHT-EMITTING DEVICE AND DISPLAY DEVICE

(71) Applicant: KYOCERA Corporation, Kyoto-shi, Kyoto (JP)

(72) Inventor: Takeshi ARAKI, Otsu-shi, Shiga (JP)

(21) Appl. No.: 18/729,333

(22) PCT Filed: Jan. 12, 2023
(86) PCT No.: PCT/JP2023/000639

§ 371 Date: Jul. 16, 2024

(30) Foreign Application Priority Data
Jan. 17, 2022 (JP) 2022-005329

(51) Int. Cl. H10H 29/34; H10H 29/30; H10H 29/80; H10H 29/855

(52) U.S. Cl. CPC H10H 29/34; H10H 29/362; H10H 29/8552; H10H 29/922; H10H 29/942

(57) ABSTRACT

A light-emitting device includes a first light emitter and a second light emitter. A first drive current through the first light emitter and a second drive current through the second light emitter flow in opposite directions. A period in which the first drive current flows and a period in which the second drive current flows at least partially overlap each other. This structure causes the phase of an electromagnetic wave induced by the first drive current to be opposite to the phase of an electromagnetic wave induced by the second drive current, thus allowing the electromagnetic waves to at least partially cancel each other and reducing electromagnetic interference.

### TECHNICAL FIELD

The present disclosure relates to a light-emitting device and a display device including multiple light emitters such as light-emitting diodes (LEDs) in one pixel.

### BACKGROUND OF INVENTION

A known light-emitting device is described in, for example, Patent Literature 1.

### CITATION LIST

### Patent Literature

Patent Literature 1: Japanese Patent No. 6252753

### SUMMARY

In an aspect of the present disclosure, a light-emitting device includes a first light emitter and a second light emitter. A first drive current through the first light emitter and a second drive current through the second light emitter flow in opposite directions. A period in which the first drive current flows and a period in which the second drive current flows at least partially overlap each other.

In an aspect of the present disclosure, a display device includes a pixel, a first light emitter included in the pixel, and a second light emitter included in the pixel. A first drive current through the first light emitter and a second drive current through the second light emitter flow in opposite directions. A period in which the first drive current flows and a period in which the second drive current flows at least partially overlap each other.

### BRIEF DESCRIPTION OF THE DRAWINGS

The objects, features, and advantages of the present disclosure will become more apparent from the following detailed description and the drawings.

FIG. 1 is a cross-sectional view of a light-emitting device according to an embodiment of the present disclosure.

FIG. 2 is a circuit diagram of the light-emitting device illustrated in FIG. 1.

FIG. 3 is a circuit diagram of a display device according to another embodiment of the present disclosure.

FIG. 4 is a circuit diagram of a display device according to another embodiment of the present disclosure.

FIG. 5 is a circuit diagram of a display device according to another embodiment of the present disclosure.

FIG. 6 is a circuit diagram of a display device according to another embodiment of the present disclosure.

FIG. 7 is a timing chart describing the operation of the light-emitting device according to the embodiment illustrated in FIG. 2.

FIG. 8 is a timing chart describing the operation of the display device according to the embodiment illustrated in FIG. 5 during parallel driving.

FIG. 9 is a timing chart describing the operation of the display device according to the embodiment illustrated in FIG. 5 during parallel driving.

FIG. 10 is a timing chart describing the operation of the display device according to the embodiment illustrated in FIG. 5 during parallel driving.

FIG. 11 is a timing chart describing the operation of the display device according to the embodiment illustrated in FIG. 5 during parallel driving.

FIG. 12 is a timing chart describing the operation of the display device according to the embodiment illustrated in FIG. 5 during series driving.

FIG. 13 is a cross-sectional view of a light-emitting device according to another embodiment of the present disclosure.

FIG. 14 is a circuit diagram of a display device including the light-emitting device illustrated in FIG. 13.

FIG. 15 is a circuit diagram of a display device according to another embodiment of the present disclosure.

### DESCRIPTION OF EMBODIMENTS

As described in Patent Literature 1, for example, a known light-emitting device includes a substrate, multiple light emitters mounted in predetermined light-emitting areas on the substrate, and switching wiring for switching electrical connection of the multiple light emitters between parallel connection and series connection.

With this known technique, the light emitters are arranged linearly and connected in series as a redundant driving row to serve as a light source. This structure may cause electromagnetic interference (EMI) resulting from magnetic fields generated on the panel surface of the display device and electromagnetic waves induced by the magnetic fields with their phases aligned with one another.

A light-emitting device 1 and a display device 10 according to one or more embodiments of the present disclosure will be described below with reference to the accompanying drawings. In an embodiment of the present disclosure, the light-emitting device 1 and the display device 10 including the light-emitting device 1 may include known components not illustrated in the figures, such as circuit boards, wiring conductors, control ICs, and LSI circuits. The figures referred to below are schematic, and are not necessarily drawn to scale relative to, for example, the actual positions and dimensional ratios of components of the light-emitting device 1 and the display device 10. In the figures, the same reference numerals denote substantially the same components. Such components will not be described repeatedly or will be described briefly.

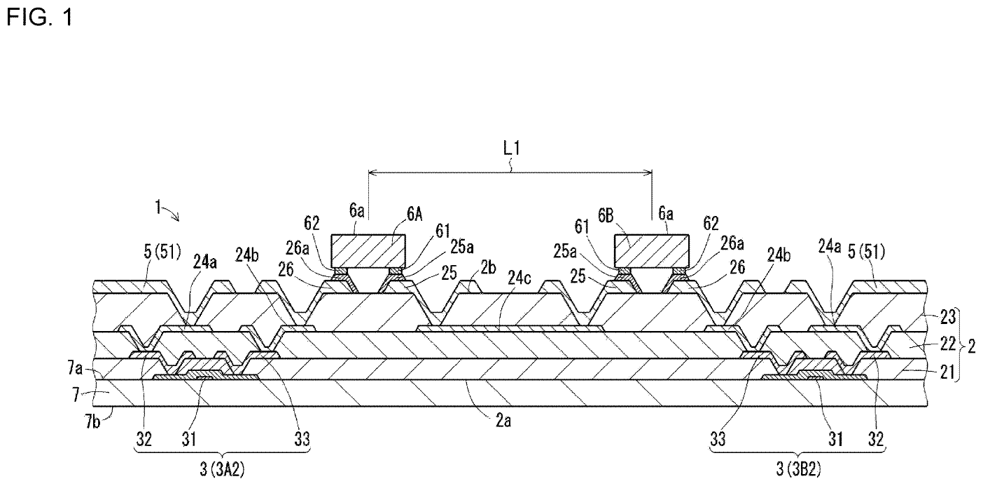

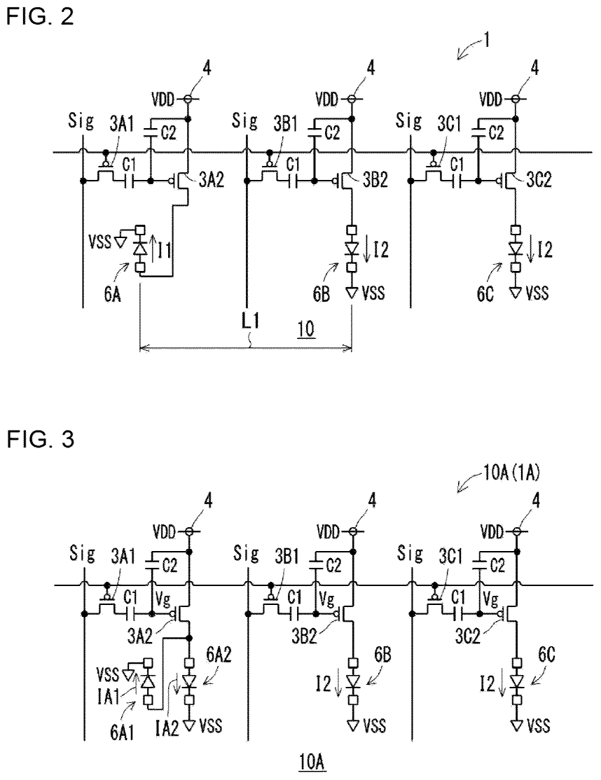

FIG. 1 is a cross-sectional view of the light-emitting device 1 according to an embodiment of the present disclosure. FIG. 2 is a circuit diagram of the display device 10 including the light-emitting device 1 illustrated in FIG. 1. In the present embodiment, the light-emitting device 1 includes a first light emitter 6A and a second light emitter 6B. The light-emitting device 1 may include an insulating substrate 2, first, second, and third switch transistors 3A1, 3B1, and 3C1, first, second, and third drive transistors 3A2, 3B2, and 3C2, a first power terminal (VDD terminal) 4, a connection conductor layer 5 connected to, for example, the first power terminal (VDD terminal), and a third light emitter 6C.

The first, second, and third switch transistors 3A1, 3B1, and 3C1 may be hereafter simply referred to as “the switch transistors 3A1, 3B1, and 3C1”. The first, second, and third drive transistors 3A2, 3B2, and 3C2 may be simply referred to as “the drive transistors 3A2, 3B2, and 3C2”. The first, second, and third switch transistors 3A1, 3B1, and 3C1 and the first, second, and third drive transistors 3A2, 3B2, and 3C2 may be collectively simply referred to as “transistors 3”. The first, second, and third light emitters 6A, 6B, and 6C may be simply referred to as “the light emitters 6A, 6B, and 6C”. The first, second, and third light emitters 6A, 6B, and 6C may be collectively simply referred to as “the light emitters 6”.

The first switch transistor 3A1 includes a gate electrode connected to a gate signal line (scanning signal line), a source electrode connected to an emission control signal line (source signal line) Sig, and a drain electrode connected to a capacitor C1. The first switch transistor 3A1 receives an on-signal transmitted through the gate signal line and input into its gate electrode. In response to the on-signal, the first switch transistor 3A1 has its channel switched to be conductive and outputs an emission control signal to the first drive transistor 3A2 through the capacitor C1. The first switch transistor 3A1 functions as a switching element for switching conduction and non-conduction of the emission control signal. The second and third switch transistors 3B1 and 3C1 also operate in the same or a similar manner.

The first drive transistor 3A2 includes a gate electrode connected to the drain electrode of the first switch transistor 3A1 and to one of the electrodes of the capacitor C1, a source electrode connected to the first power terminal 4 and the other of the electrodes of the capacitor C1, and a drain electrode connected to an anode terminal of the first light emitter 6A. The first drive transistor 3A2 drives the first light emitter 6A with a current based on the potential difference between a first power supply voltage VDD and a second power supply voltage VSS corresponding to the level (voltage) of the emission control signal. The second and third drive transistors 3B2 and 3C2 also operate in the same or a similar manner.

A first drive current I1 through the first light emitter 6A and a second drive current I2 through the second light emitter 6B flow in opposite directions. A period in which the first drive current I1 flows and a period in which the second drive current I2 flows at least partially overlap each other. This structure produces the effects described below. A magnetic field (magnetic field MF1) resulting from the first drive current I1 flowing through the first light emitter 6A in accordance with the right hand screw rule and an electromagnetic wave induced by the magnetic field have a phase opposite to the phase of a magnetic field (magnetic field MF2) resulting from the second drive current I2 flowing through the second light emitter 6B and an electromagnetic wave induced by the magnetic field. For a period of an at least partial overlap between the period in which the first drive current I1 flows and the period in which the second drive current I2 flows, an electromagnetic wave (electromagnetic wave EM1) generated based on the magnetic field MF1 and an electromagnetic wave (electromagnetic wave EM2) generated based on the magnetic field MF2 at least partially cancel each other.

This weakens the electromagnetic wave EM1 and the electromagnetic wave EM2, thus reducing electromagnetic interference resulting from the electromagnetic waves EM1 and EM2.

The first drive current I1 and the second drive current I2 may not flow in exact opposite directions. The electromagnetic wave EM1 and the electromagnetic wave EM2 can cancel each other although the directions are not exact opposite. The direction of the first drive current I1 and the direction of the second drive current I2 may be at a crossing angle greater than 0° and less than or equal to about 45°. The crossing angle may be greater than 0° and less than or equal to about 30°, or greater than 0° and less than or equal to about 10°. For the crossing angle being 0°, the electromagnetic wave EM1 and the electromagnetic wave EM2 may cancel each other most effectively.

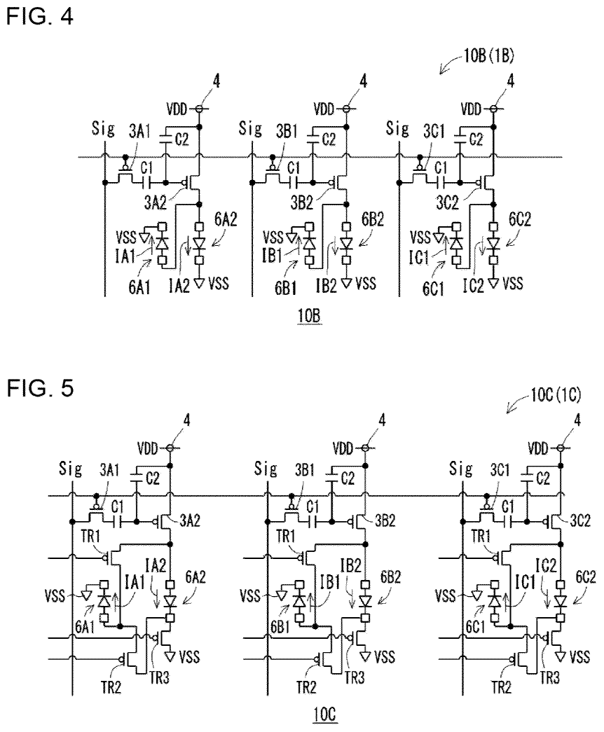

As illustrated in FIG. 2, the first light emitter 6A and the second light emitter 6B may be aligned in a direction perpendicular to the parallel directions of the first drive current I1 and the second drive current I2. This structure increases the overlap between the electromagnetic wave EM1 and the electromagnetic wave EM2, thus allowing the electromagnetic wave EM1 and the electromagnetic wave EM2 to cancel each other more effectively. In the above structure, as illustrated in FIG. 4, the first light emitter 6A and the second light emitter 6B may be located close to each other. This structure further increases the overlap between the electromagnetic wave EM1 and the electromagnetic wave EM2, thus allowing the electromagnetic wave EM1 and the electromagnetic wave EM2 to cancel each other effectively still further.

A vector indicating the direction of the first drive current I1 and a vector indicating the direction of the second drive current I2 may be located on a single straight line. In other words, the first light emitter 6A and the second light emitter 6B may be located on a single straight line. This structure allows the electromagnetic wave EM1 and the electromagnetic wave EM2 to cancel each other effectively, and allows the first light emitter 6A and the second light emitter 6B to be located closer to each other.

A period of an at least partial overlap (overlap period TW) between the period (T1) in which the first drive current I1 flows and the period (T2) in which the second drive current I2 flows may be, for example, half or more of the period T1 when the periods T1 and T2 have the same length. In this case, the period in which the electromagnetic wave EM1 and the electromagnetic wave EM2 cancel each other is longer than or equal to the period in which the electromagnetic wave EM1 and the electromagnetic wave EM2 do not cancel each other. This structure thus reduces electromagnetic interference more effectively. The overlap period TW may be 70% or more, 90% or more, or 100% of the period T1. For the overlap period TW being 100% of the period T1, the electromagnetic wave EM1 and the electromagnetic wave EM2 may cancel each other most effectively. When the period T1 and the period T2 have different lengths, the overlap period TW may be half or more of the shorter one of the periods T1 and T2. The overlap period TW may be 70% or more, 90% or more, or 100% of the shorter one of the periods T1 and T2.

In the present embodiment illustrated in FIG. 2, the drive current I2 flows through the second light emitter 6B in the same direction as a drive current I3 flowing through the third light emitter 6C. The first light emitter 6A may emit, for example, red light. The second light emitter 6B may emit green light. The third light emitter 6C may emit blue light. Each of the first light emitter 6A, the second light emitter 6B, and the third light emitter 6C forms a subpixel. The three light emitters 6A, 6B, and 6C form one pixel. The first drive current I1 through the first light emitter 6A is greater than the drive current I2 through the second light emitter 6B and the drive current I3 through the third light emitter 6C (I1>I2 and I1>I3). First light emitters 6A and second light emitters 6B mounted on the light-emitting device 1 are all arranged to cause the drive current I1 and the drive current I2 to flow in opposite directions. This arrangement weakens the electromagnetic waves EM1 and EM2 generated during emission, thus reducing electromagnetic interference.

In the structure in FIG. 2, the drive current I2 and the drive current I3 may flow in opposite directions. The drive current I1 and the drive current I3 then flow in the same direction. For example, when the drive current I2 is at the maximum, the electromagnetic wave EM2 is at the maximum. The electromagnetic wave EM1 and an electromagnetic wave EM3 are located across the electromagnetic wave EM2 and thus can effectively weaken the electromagnetic wave EM2.

The structure may have a distance L1 between the first light emitter 6A and the second light emitter 6B to be less than or equal to a maximum distance Lmax (L1≤Lmax), where Lmax is the maximum distance at which the magnetic field MF1 generated by the first drive current I1 and the magnetic field MF2 generated by the second drive current I2 interact with each other. In this structure, the first light emitter 6A and the second light emitter 6B are located within a range less than or equal to the maximum distance Lmax at which the electromagnetic wave EM1 and the electromagnetic wave EM2 substantially interact with each other. Thus, the electromagnetic wave EM1 and the electromagnetic wave EM2 cancel each other more effectively. The maximum distance Lmax can be determined as appropriate based on the strength of the magnetic field MF1 proportional to the first drive current I1 and the strength of the magnetic field MF2 proportional to the second drive current I2. The maximum distance Lmax may be, for example, about 300 μm, about 100 μm, or about 30 μm.

The maximum distance Lmax may be defined as described below. The first drive current I1 generates a first magnetic field that induces a first electric field, the first electric field induces a second magnetic field, and the second magnetic field induces a second electric field. This is repeated to generate the electromagnetic wave EM1. The distance at which the n-th magnetic field (n is a natural number) in the electromagnetic wave EM1 causes a significant variation (e.g., a variation of about 3 to 10%) in the second drive current I2 may be defined as about half the maximum distance Lmax for the electromagnetic wave EM1. In the same or a similar manner, the distance at which the m-th magnetic field (m is a natural number) in the electromagnetic wave EM2 causes a significant variation (e.g., a variation of about 3 to 10%) in the first drive current I1 may be defined as about half the maximum distance Lmax for the electromagnetic wave EM2. About half the maximum distance Lmax for the electromagnetic wave EM1 and about half the maximum distance Lmax for the electromagnetic wave EM2 may be added to obtain the maximum distance Lmax.

The first drive current I1 may have the same magnitude as the second drive current I2 (I1=I2). In this case, the electromagnetic wave EM1 and the electromagnetic wave EM2 have the same intensity. The electromagnetic wave EM1 and the electromagnetic wave EM2 can thus cancel each other more effectively.

The first light emitter 6A may be connected to a connection wire (LC1) including a portion parallel to a portion of a connection wire (LC2) connected to the second light emitter 6B. This structure allows an electromagnetic wave generated in the parallel portion in the connection wire LC1 and an electromagnetic wave generated in the parallel portion in the connection wire LC2 to cancel each other. This structure thus further reduces electromagnetic interference. The parallel portion in the connection wire LC1 and the parallel portion in the connection wire LC2 may be located inside the insulating substrate 2. In this case, the insulating substrate 2 weakens the electromagnetic wave generated in the parallel portion in the connection wire LC1 and the electromagnetic wave generated in the parallel portion in the connection wire LC2. These electromagnetic waves thus cancel each other more effectively. This structure thus further reduces electromagnetic interference.

The first light emitter 6A may include at least a portion or at least a surface covered with an insulating layer. This structure can weaken the electromagnetic wave EM1. In the same or a similar manner, the second light emitter 6B may include at least a portion or at least a surface covered with an insulating layer. This structure can weaken the electromagnetic wave EM2. The electromagnetic wave EM1 and the electromagnetic wave EM2 thus cancel each other more effectively to further reduce the electromagnetic interference. The insulating layer may be an organic insulating layer of an acrylic resin, a polycarbonate resin, or other materials, or an inorganic insulating layer of silicon oxide (SiO₂), silicon nitride (Si₃N₄), or other materials.

The first light emitter 6A may include a portion or a surface covered with an insulating layer at a position farthest from the second light emitter 6B. This structure can weaken the electromagnetic wave EM1 radiated in a direction opposite to the second light emitter 6B. This structure can also avoid decreasing the electromagnetic wave EM1 that is radiated toward the second light emitter 6B to undergo cancellation. This structure can thus effectively weaken the electromagnetic wave EM1. The second light emitter 6B may have the same or a similar structure.

In the structure in FIG. 2, when the light emitters 6A, 6B, and 6C emit light, the electromagnetic wave (electromagnetic wave EM3) induced by a magnetic field (magnetic field MF3) generated by the drive current I3 flowing through the third light emitter 6C are canceled by the electromagnetic wave EM1. In other words, the electromagnetic wave EM1 is canceled by the electromagnetic wave EM2 and the electromagnetic wave EM3. For example, the electromagnetic wave EM1 with the highest intensity can be canceled more effectively. This structure thus further reduces electromagnetic interference.

In the present embodiment, a first subpixel may include a switching element located on a connection wire connecting the drain electrode of the first drive transistor 3A2 and the anode terminal of the first light emitter 6A. The switching element may control the emission or non-emission state of the first light emitter 6A. The switching element may be a p-channel thin film transistor (TFT) that is the same as or similar to the first drive transistor 3A2. A second subpixel and a third subpixel may each have the same or a similar structure. The insulating substrate 2 includes a first surface (one main surface) 2a and a second surface (the other main surface) 2b opposite to the first surface 2a. The insulating substrate 2 may be, for example, a triangular plate, a quadrangular plate such as a square plate or a rectangular plate, a trapezoidal plate, a hexagonal plate, a circular plate, an oval plate, or a plate with any other shape. The insulating substrate 2 may have a single-layer structure including a single insulating layer, or may have a multilayer structure including multiple insulating layers stacked on one another. In other words, the insulating substrate 2 may be a stack of insulating layers. In the present embodiment, the insulating substrate 2 includes multiple insulating layers 21, 22, and 23 stacked on one another as illustrated in, for example, FIG. 1. The insulating layers 21, 22, and 23 may be, for example, inorganic insulating layers of silicon oxide (SiO₂), silicon nitride (Si₃N₄), or other materials, or organic insulating layers of, for example, an acrylic resin, a polyimide resin, a polycarbonate resin, or other materials. For example, the insulating layers 21 and 22 in a lower portion (closer to a substrate 7) of the insulating substrate 2 may be inorganic insulating layers, and the insulating layer 23 in an upper portion of the insulating substrate 2 may be an organic insulating layer as a planarization layer thicker than each of the insulating layers 21 and 22. The insulating layers 21, 22, and 23 may be the same or different from one another in composition, dimensions (thickness), and other features.

The insulating substrate 2 includes internal wires 24a to 24c. The internal wires 24a to 24c electrically connect, for example, the drive transistors 3A2 and 3B2, the power terminal 4, the connection conductor layer 5, and the light emitters 6A and 6B to one another. The internal wires 24a to 24c may be located between adjacent ones of the insulating layers 21, 22, and 23 as illustrated in, for example, FIG. 1. The internal wires 24a to 24c may be made of, for example, Mo/Al/Mo, MoNd/AlNd/MoNd, or other materials. “Mo/Al/Mo” indicates a structure including a Mo layer, an A1 layer, and a Mo layer stacked in this order. The same applies to other notations. MoNd indicates an alloy of Mo and Nd, and the same applies to other notations.

The insulating substrate 2 includes an anode electrode wire 26 and a cathode electrode wire 25. The cathode electrode wire 25 electrically connects the internal wire 24c and a cathode terminal 61 of the light emitter 6. The internal wire 24c is electrically connected to a second power terminal (VSS terminal). The anode electrode wire 26 electrically connects the internal wire 24b and an anode terminal 62 of the light emitter 6. The cathode electrode wire 25 and the anode electrode wire 26 may be located on the second surface 2b, or between adjacent ones of the insulating layers 21, 22, and 23. The cathode electrode wire 25 may be directly connected to the cathode terminal 61, or may be connected to the cathode terminal 61 with a transparent conductive layer 25a between them. The anode electrode wire 26 may be directly connected to the anode terminal 62, or may be connected to the anode terminal 62 with a transparent conductive layer 26a between them. In the example in FIG. 1, the cathode electrode wire 25 is connected to the cathode terminal 61 with the transparent conductive layer 25a between them, and the anode electrode wire 26 is connected to the anode terminal 62 with the transparent conductive layer 26a between them. The transparent conductive layers 25a and 26a may each be made of a transparent conductor, such as indium tin oxide (ITO) or indium zinc oxide (IZO).

The substrate 7 may be made of, for example, a glass material, a ceramic material, or a resin material. Examples of the glass material used for the substrate 7 include borosilicate glass, crystallized glass, and quartz. Examples of the ceramic material used for the substrate 7 include alumina (Al₂O₃), zirconia (ZrO₂), silicon nitride (Si₃N₄), silicon carbide (SiC), and aluminum nitride (AlN). Examples of the resin material used for the substrate 7 include an epoxy resin, a polyimide resin, a polyamide resin, an acrylic resin, and a polycarbonate resin.

The substrate 7 may be made of, for example, a metal material, an alloy material, a semiconductor material, or other materials. Examples of the metal material used for the substrate 7 include aluminum (Al), magnesium (Mg) (specifically, high-purity magnesium with Mg content of 99.95% or higher), zinc (Zn), tin (Sn), copper (Cu), chromium (Cr), and nickel (Ni). Examples of the alloy material used for the substrate 7 include duralumin (an Al—Cu alloy, an Al—Cu—Mg alloy, or an Al—Zn—Mg—Cu alloy), which is an aluminum alloy containing aluminum as a main component, a magnesium alloy (a Mg—Al alloy, a Mg—Zn alloy, or a Mg—Al—Zn alloy) containing magnesium as a main component, titanium boride, stainless steel, and a Cu—Zn alloy. Examples of the semiconductor material used for the substrate 7 include silicon (Si), germanium (Ge), and gallium arsenide (GaAs).

For the substrate 7 made of a metal material, an alloy material, or a semiconductor material, insulating layers (not illustrated) of silicon oxide (SiO₂), silicon nitride (Si₃N₄), or other materials may be located between the switch transistors 3A1, 3B1, and 3C1 and the substrate 7 or between the drive transistors 3A2, 3B2, and 3C2 and the substrate 7.

Each transistor 3 is located inside the insulating substrate 2 or on the first surface 2a of the insulating substrate 2. The transistor 3 controls the light emitting operation (the emission or non-emission state and the light intensity) of the light emitter 6. The transistor 3 may be, for example, a TFT. The transistor 3 may include a semiconductor film (also referred to as a channel) of, for example, amorphous silicon (a-Si), low-temperature polycrystalline silicon (LTPS), or other materials. The transistor 3 may include three terminals, or specifically, a gate electrode 31, a source electrode 32, and a drain electrode 33. The transistor 3 switches, based on the voltage applied to the gate electrode 31, conduction (on-state) and non-conduction (off-state) between the source electrode 32 and the drain electrode 33.

In the example described below, the transistor 3 is a TFT including a semiconductor film (channel), the gate electrode 31, the source electrode 32, and the drain electrode 33. The transistor 3 may be an n-channel TFT or a p-channel TFT.

The first power terminal 4 (illustrated in FIG. 2) as a power feeder is connected to an external power supply (not illustrated). The first power terminal 4 receives a power supply voltage (VDD voltage of, for example, 3 to 15 V). The first power terminal 4 may be located inside the insulating substrate 2 (illustrated in FIG. 1) or on the second surface 2b of the insulating substrate 2, or may be located on a third surface 7a of the substrate 7. The first power terminal 4 may be located on a periphery of the second surface 2b, or on a periphery of the third surface 7a. Multiple first power terminals 4 may be arranged. One or more first power terminals 4 may be arranged. One or more second power terminals (also referred to as a second power feeder) may be arranged. The first power terminal 4 receives the first power supply voltage VDD. The second power terminal receives the second power supply voltage VSS (e.g., −3 to 0 V) lower than the first power supply voltage VDD. The first power supply voltage VDD and the second power supply voltage VSS are predetermined as appropriate for the type of the light emitters 6 and other conditions. The first power terminal 4 and the second power terminal may be made of, for example, Al, Al/Ti, Ti/Al/Ti, Mo, Mo/Al/Mo, MoNd/AlNd/MoNd, Cu, Cr, Ni, Ag, or other materials.

The connection conductor layer 5 (illustrated in FIG. 1) connects, for example, the source electrode 32 of the drive transistor 3A2 and the first power terminal 4. The connection conductor layer 5 feeds the first power supply voltage at a level corresponding to the drive current to the source electrode 32 of the drive transistor 3A2. The connection conductor layer 5 may be located on the second surface 2b, or between adjacent ones of the insulating layers 21, 22, and 23. The connection conductor layer 5 may include a portion on the second surface 2b, and another portion between adjacent ones of the insulating layers 21, 22, and 23. The connection conductor layer 5 may be made of, for example, Mo/Al/Mo, MoNd/AlNd/MoNd, or other materials. The connection conductor layer 5 may be a transparent conductor of, for example, ITO or IZO.

The three light emitters 6A, 6B, and 6C illustrated in FIG. 2 are located on the second surface 2b of the insulating substrate 2. The light emitters 6A, 6B, and 6C may each be, for example, a self-luminous element such as a light-emitting diode (LED) or a semiconductor laser diode (LD). In the present embodiment, the light emitters 6A, 6B, and 6C are LEDs. The light emitters 6A, 6B, and 6C may be micro-LEDs (μLEDs). In this case, the light emitter 6 may be quadrangular and has each side with a length of about 1 to 100 μm inclusive, or about 5 to 20 μm inclusive as viewed in a direction perpendicular to its light-emitting surface 6a. When the light emitter 6 is a μLED, the first power supply voltage VDD may be, for example, about 10 to 15 V, and the second power supply voltage VSS may be, for example, about 0 to 3 V.

Each of the light emitters 6A, 6B, and 6C is a two-terminal element including the cathode terminal 61 and the anode terminal 62. The cathode terminal 61 is electrically connected to the cathode electrode wire 25, and the anode terminal 62 is electrically connected to the anode electrode wire 26 as illustrated in, for example, FIG. 1.

The light-emitting device 1 may form a display device. The display device includes multiple pixels each including multiple light emitters 6A, 6B, and 6C located on the second surface 2b, as well as switch transistors 3A1, 3B1, and 3C1 and drive transistors 3A2, 3B2, and 3C2 for driving the light emitters 6A, 6B, and 6C. The multiple pixels are arranged in a matrix. More specifically, the first light emitter 6A, the first switch transistor 3A1, and the first drive transistor 3A2 form the first subpixel. The second light emitter 6B, the second switch transistor 3B1, and the second drive transistor 3B2 form the second subpixel. The third light emitter 6C, the third switch transistor 3C1, and the third drive transistor 3C2 form the third subpixel. One pixel includes the first to third subpixels.

For example, the first light emitter 6A may be a red light emitter that emits red light, the second light emitter 6B may be a green light emitter that emits green light, and the third light emitter 6C may be a blue light emitter that emits blue light. The drive current for the red light emitter is typically greater than the drive current for the green light emitter and the drive current for the blue light emitter.

FIG. 3 is a circuit diagram of a display device 10A according to another embodiment of the present disclosure. The same reference numerals denote the components corresponding to those in the embodiment described above. FIG. 3 is a circuit diagram of one pixel. The display device 10A includes a light-emitting device 1A. Each pixel in the display device 10A includes first, second, and third light emitters 6A1 (6A2), 6B, and 6C, first, second, and third switch transistors 3A1, 3B1, and 3C1, and first, second, and third drive transistors 3A2, 3B2, and 3C2. The first, second, and third switch transistors 3A1, 3B1, and 3C1 and the first, second, and third drive transistors 3A2, 3B2, and 3C2 are p-channel TFTs. Each subpixel includes capacitors C1 and C2.

The first, second, and third drive transistors 3A2, 3B2, and 3C2 include the respective source electrodes each connected to the corresponding first power terminal 4 to which the first power supply voltage VDD is applied. The first, second, and third drive transistors 3A2, 3B2, and 3C2 include the respective drain electrodes connected to the respective anode terminals of the first, second, and third light emitters 6A1 (6A2), 6B, and 6C. The capacitors C1 and C2 maintain the level (voltage) of an emission control signal that is written into a pixel node Vg from an emission control signal line Sig for a predetermined period (e.g., a period of one frame). The first, second, and third drive transistors 3A2, 3B2, and 3C2 drive the first, second, and third light emitters 6A1 (6A2), 6B, and 6C with a current based on the potential difference between the first power supply voltage VDD and the second power supply voltage VSS corresponding to the level (voltage) of the emission control signal.

In the present embodiment, the first subpixel includes two first light emitters 6A1 and 6A2 that are connected in parallel. A drive current IA1 through the first light emitter 6A1 and a drive current IA2 through the first light emitter 6A2 flow in opposite directions. The period in which the drive current IA1 flows and the period in which the drive current IA2 flows are simultaneous with and overlap each other. For example, when the two first light emitters 6A1 and 6A2 are red light emitters, each of the drive currents IA1 and IA2 is greater than the drive currents I2 and I3. Thus, each of the electromagnetic wave EM1 induced by the drive current IA1 and the electromagnetic wave EM1 induced by the drive current IA2 has higher intensity than the electromagnetic waves EM2 and EM3. To reduce electromagnetic interference resulting from the electromagnetic wave EM1 generated from the first light emitter 6A1 and the electromagnetic wave EM1 generated from the first light emitter 6A2, the electromagnetic waves EM1 have opposite phases to cancel each other. This effectively reduces electromagnetic interference resulting from the electromagnetic waves EM1.

In the example described below, the electromagnetic wave EM1 generated by the drive current IA1 through the first light emitter 6A1 may be referred to as an electromagnetic wave EM1 (A), and the electromagnetic wave EM1 generated by the drive current IA2 through the first light emitter 6A2 may be referred to as an electromagnetic wave EM1(B).

For the first subpixel, the drive current IA1 through the first light emitter 6A1 may be a first drive current, and the drive current IA2 through the first light emitter 6A2 may be a second drive current. The first light emitter 6A1 may be referred to as a first-A light emitter 6A1, and the first light emitter 6A2 may be referred to as a first-B light emitter 6A2. The same or similar components may be hereafter referred to in the same or a similar manner.

In the present embodiment, the first subpixel may include a switching element located on a connection wire connecting the drain electrode of the first drive transistor 3A2 and the anode terminal of the first light emitter 6A1 (first-A light emitter 6A1). A switching element may be located on a connection wire connecting the drain electrode of the first drive transistor 3A2 and the anode terminal of the first light emitter 6A2 (first-B light emitter 6A2). This structure allows the switching elements to control the emission or non-emission state of the first light emitters 6A1 and 6A2. The second subpixel and the third subpixel may each have the same or a similar structure.

FIG. 4 is a circuit diagram of a display device 10B according to another embodiment of the present disclosure. The same reference numerals denote the components corresponding to those in the embodiments described above. The display device 10B includes a light-emitting device 1B. FIG. 4 is a circuit diagram of one pixel. Each pixel in the display device 10B includes first, second, and third light emitters 6A1 (6A2), 6B1 (6B2), and 6C1 (6C2), first, second, and third switch transistors 3A1, 3B1, and 3C1, and first, second, and third drive transistors 3A2, 3B2, and 3C2. The first, second, and third switch transistors 3A1, 3B1, and 3C1 and the first, second, and third drive transistors 3A2, 3B2, and 3C2 are p-channel TFTs. Each subpixel includes capacitors C1 and C2.

In the first subpixel in the display device 10B according to the present embodiment, the first drive current IA1 through the first light emitter 6A1 and the first drive current IA2 through the first light emitter 6A2 flow in opposite directions. Thus, the electromagnetic wave EM1 (electromagnetic wave EM1(A)) induced by the first drive current IA1 has a phase opposite to the phase of the electromagnetic wave EM1 (electromagnetic wave EM1(B)) induced by the first drive current IA2. The period in which the first drive current IA1 flows and the period in which the first drive current IA2 flows are simultaneous with and overlap each other. The electromagnetic waves EM1 thus cancel each other.

In the second subpixel, a second drive current IB1 through the second light emitter 6B1 and a second drive current IB2 through the second light emitter 6B2 flow in opposite directions. Thus, the electromagnetic wave EM2 induced by the second drive current IB1 has a phase opposite to the phase of the electromagnetic wave EM2 induced by the second drive current IB2. The period in which the second drive current IB1 flows and the period in which the second drive current IB2 flows are simultaneous with and overlap each other. The electromagnetic waves EM2 thus cancel each other.

In the third subpixel, a third drive current IC1 through the third light emitter 6C1 and a third drive current IC2 through the third light emitter 6C2 flow in opposite directions. Thus, the electromagnetic wave EM3 induced by the third drive current IC1 has a phase opposite to the phase of the electromagnetic wave EM3 induced by the third drive current IC2. The period in which the third drive current IC1 flows and the period in which the third drive current IC2 flows are simultaneous with and overlap each other. The electromagnetic waves EM3 thus cancel each other.

This weakens the electromagnetic wave EM1 generated from the first light emitter 6A1, the electromagnetic wave EM1 from the first light emitter 6A2, the electromagnetic wave EM2 from the second light emitter 6B1, the electromagnetic wave EM2 from the second light emitter 6B2, the electromagnetic wave EM3 from the third light emitter 6C1, and the electromagnetic wave EM3 from the third light emitter 6C2, thus effectively reducing electromagnetic interference.

In the present embodiment, the first light emitter 6A1 and the first light emitter 6A2 are at a distance less than or equal to a maximum distance at which a magnetic field generated by the first drive current IA1 and a magnetic field generated by the first drive current IA2 interact with each other. The distance between the first light emitter 6A1 and the first light emitter 6A2 is set to about 30 μm.

In the present embodiment, the first subpixel may include a switching element located on a connection wire connecting a drain electrode of the first drive transistor 3A2 and an anode terminal of the first light emitter 6A1 and a switching element located on a connection wire connecting the drain electrode of the first drive transistor 3A2 and an anode terminal of the first light emitter 6A2. The switching elements may control the emission or non-emission state of the first light emitters 6A1 and 6A2. The second subpixel and the third subpixel may each have the same or a similar structure.

FIG. 5 is a circuit diagram of a display device 10C according to another embodiment of the present disclosure. The same reference numerals denote the components corresponding to those in the embodiments described above. FIG. 5 is a circuit diagram of one pixel. Each pixel in the display device 10C includes first, second, and third light emitters 6A1 (6A2), 6B1 (6B2), and 6C1 (6C2), first, second, and third switch transistors 3A1, 3B1, and 3C1, and first, second, and third drive transistors 3A2, 3B2, and 3C2. The first, second, and third switch transistors 3A1, 3B1, and 3C1 and the first, second, and third drive transistors 3A2, 3B2, and 3C2 are p-channel TFTs. Each subpixel includes capacitors C1 and C2 and switching transistors TR1 to TR3 (hereafter also referred to as a first switching transistor TR1, a second switching transistor TR2, and a third switching transistor TR3).

In the first subpixel, the switching transistors TR1 to TR3 connect the first light emitters 6A1 and 6A2 in series or in parallel to allow the first light emitters 6A1 and 6A2 to emit light simultaneously. Additionally, this structure also allows either the first light emitter 6A1 or 6A2 to emit light. The second subpixel and the third subpixel each have the same or a similar structure.

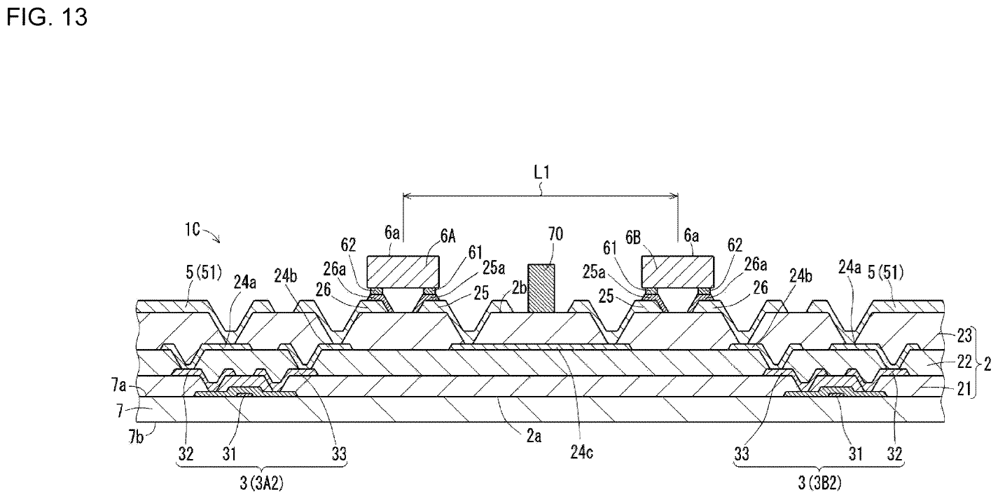

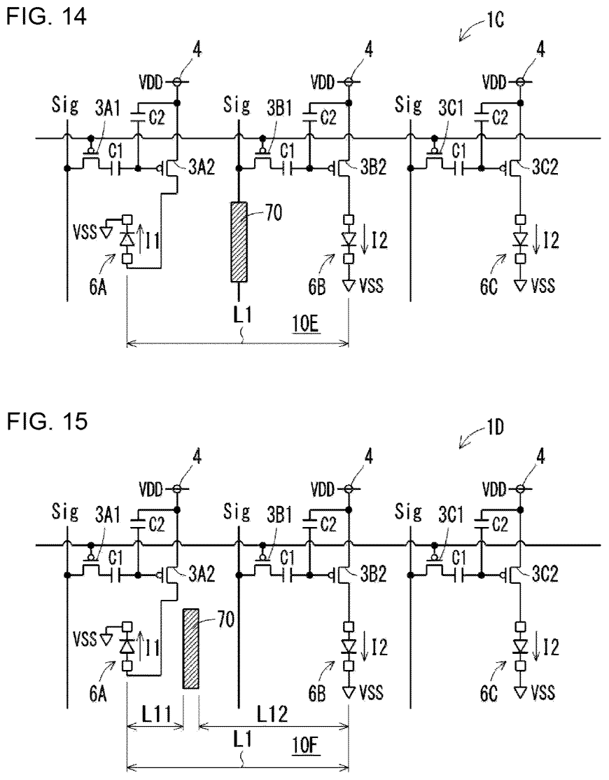

FIG. 13 is a cross-sectional view of a light-emitting device 1C according to another embodiment of the present disclosure. FIG. 14 is a circuit diagram of a display device 10E including the light-emitting device 1C illustrated in FIG. 13. The same reference numerals denote the components corresponding to those in the above embodiments. Such components will not be described repeatedly. In the present embodiment, the display device 10E includes the light-emitting device 1C. As illustrated in FIGS. 13 and 14, the light-emitting device 1C may include an electromagnetic wave shield 70 between the first light emitter 6A and the second light emitter 6B. The electromagnetic wave shield 70 is, for example, linear or strip-shaped. The electromagnetic wave shield 70 is made of a conductive material or a semiconductor material. Examples of the conductive material may include, for example, A1, Al/Ti, Ti/Al/Ti, Mo, Mo/Al/Mo, MoNd/AlNd/MoNd, Cu, Cr, Ni, and Ag. Examples of the semiconductor material may include Si, Ge, and GaAs. The above structure weakens the electromagnetic wave EM1 and the electromagnetic wave EM2 more effectively, thus further reducing electromagnetic interference resulting from the electromagnetic waves EM1 and EM2. The electromagnetic wave shield 70 may be electrically connected to the internal wire 24c that is electrically connected to the second power terminal (VSS terminal). In this structure, an inductive current generated from the first drive current I1 and the second drive current I2 in the electromagnetic wave shield 70 can flow through the internal wire 24c to a low potential portion such as a ground potential portion. This structure more effectively weakens the electromagnetic wave EM1 and the electromagnetic wave EM2, thus further reducing electromagnetic interference resulting from the electromagnetic waves EM1 and EM2.

FIG. 15 is a circuit diagram of a display device 10D according to another embodiment of the present disclosure. The same reference numerals denote the components corresponding to those in the above embodiments. Such components will not be described repeatedly. In the present embodiment, as illustrated in FIG. 15, the display device 10D includes an electromagnetic wave shield 70. When the first drive current I1 and the second drive current I2 have different magnitudes, the electromagnetic wave shield 70 may be located closer to one of the first light emitter 6A or the second light emitter 6B having a greater drive current. In FIG. 15, the first drive current I1 is greater than the second drive current I2. The electromagnetic wave shield 70 is located closer to the first light emitter 6A than to the second light emitter 6B. For example, when the first light emitter 6A is an LED that emits red light and the second light emitter 6B is an LED that emits green light, the first drive current I1 may be about 10 times greater than the second drive current I2. In this case, the electromagnetic wave EM1 generated by the first drive current I1 has higher intensity than the electromagnetic wave EM2 generated by the second drive current I2. The electromagnetic wave shield 70 located closer to the first light emitter 6A than to the second light emitter 6B can efficiently shield the electromagnetic wave EM1 having higher intensity generated by the first drive current I1. The above structure weakens the electromagnetic wave EM1 and the electromagnetic wave EM2 more effectively, thus further reducing electromagnetic interference resulting from the electromagnetic waves EM1 and EM2. The ratio L11/L12 of a distance L11 between the electromagnetic wave shield 70 and the first light emitter 6A to a distance L12 between the electromagnetic wave shield 70 and the second light emitter 6B may be about 0.1 to 0.9, depending on the magnitudes of the first drive current I1 and the second drive current I2. The range is not limited to this example.

The electromagnetic wave shield 70 may have a length in the direction along the first drive current I1 (the length may be the length in the direction along the second drive current I2) greater than or equal to the length of the first light emitter 6A in the direction along the first drive current I1 (the length may be the length of the second light emitter 6B in the direction along the second drive current I2). In the first light emitter 6A, an electromagnetic wave generated by the first drive current I1 is more likely to spread spatially. The length of the electromagnetic wave shield 70 in the direction along the first drive current I1 may be, but not limited to, more than one times and five times or less than the length of the first light emitter 6A in the direction along the first drive current I1.

The electromagnetic wave shield 70 may include an upper surface at a height (thickness) greater than or equal to the height of the path of the first drive current I1 in the first light emitter 6A, and may include the upper surface at a height (thickness) greater than or equal to the height of the path of the second drive current I2 in the second light emitter 6B. In this structure, the electromagnetic wave shield 70 can effectively shield the electromagnetic wave EM1 and the electromagnetic wave EM2 when any electromagnetic wave EM1 resulting from the first drive current I1 and any electromagnetic wave EM2 resulting from the second drive current I2 spread spatially.

The electromagnetic wave shield 70 may have a width of, but is not limited to, about 0.01 to 10 μm in a plan view. The electromagnetic wave shield 70 may be formed in the same process as for forming the cathode electrode wire 25 and the anode electrode wire 26. Multiple electromagnetic wave shields 70 may be arranged parallel to one another.

The electromagnetic wave shield 70 may be a magnetic shield. The magnetic shield also functions as a magnetic absorber. The magnetic shield may be made of a ferromagnetic material with a high relative magnetic permeability, including iron, cobalt, and nickel. When an external magnetic field is blocked, the ferromagnetic material loses its magnetization and returns to the original state as a soft magnetic material. For example, the magnetic shield may be made of silicon steel (iron (Fe) containing about 3 mass % of silicon (Si) with a relative magnetic permeability of about 4000), directional silicon steel, Permalloy (a Ni—Fe alloy, a Ni—Cu—Fe alloy, a Ni—Mo—Fe alloy, a Ni—Cu—Mo—Fe alloy, or a Ni—Cu—Mo—Cr—Fe alloy with a relative magnetic permeability of about 50000 to 200000), Sendust (an Fe—Si—Al alloy with a relative magnetic permeability of about 120000), ferrite (a sintered magnetic material (ceramic magnetic material) in which Co, Ni, Mn, and other materials are mixed and sintered with iron oxide (Fe₂O₄) as a main component, a ceramic magnetic material in which Ba, SR, Pb, and other materials are mixed and sintered with Fe₁₂O₁₉ as a main component, or a ceramic magnetic material in which rare earth elements (e.g., Y) are mixed and sintered with Fe₅O₁₂ as a main component with a relative magnetic permeability of about 16 to 640), or other materials. For example, a Ni—Fe alloy refers to an alloy containing Ni and Fe. The above structure weakens the electromagnetic wave EM1 and the electromagnetic wave EM2 more effectively, thus further reducing electromagnetic interference resulting from the electromagnetic waves EM1 and EM2.

When the first drive current I1 and the second drive current I2 have different magnitudes, the magnetic shield may be located closer to one of the first light emitter 6A or the second light emitter 6B having a greater drive current. For example, when the first light emitter 6A is an LED that emits red light and the second light emitter 6B is an LED that emits green light, the first drive current I1 may be about 10 times greater than the second drive current I2. In this case, the magnetic field generated by the first drive current I1 has higher intensity than the magnetic field generated by the second drive current I2. The magnetic shield located closer to the first light emitter 6A than to the second light emitter 6B can efficiently absorb the magnetic field with higher intensity generated by the first drive current I1. The above structure weakens the electromagnetic wave EM1 and the electromagnetic wave EM2 more effectively, thus further reducing electromagnetic interference resulting from the electromagnetic waves EM1 and EM2. The ratio L11/L12 of the distance L11 between the magnetic shield and the first light emitter 6A to the distance L12 between the magnetic shield and the second light emitter 6B may be about 0.1 to 0.9, depending on the magnitudes of the first drive current I1 and the second drive current I2. The range is not limited to this example.

The magnetic shield may have a length in the direction along the first drive current I1 (the length may be the length in the direction along the second drive current I2) greater than or equal to the length of the first light emitter 6A in the direction along the first drive current I1 (the length may be the length of the second light emitter 6B in the direction along the second drive current I2). In the first light emitter 6A, the magnetic field generated by the first drive current I1 is more likely to spread spatially. The length of the magnetic shield in the direction along the first drive current I1 may be, but not limited to, more than one times and five times or less than the length of the first light emitter 6A in the direction along the first drive current I1.

The magnetic shield may include an upper surface at a height (thickness) greater than or equal to the height of the path of the first drive current I1 in the first light emitter 6A, and may include the upper surface at a height (thickness) greater than or equal to the height of the path of the second drive current I2 in the second light emitter 6B. In this structure, the magnetic shield can effectively shield the electromagnetic wave EM1 and the electromagnetic wave EM2 when any magnetic field resulting from the first drive current I1 and any magnetic field resulting from the second drive current I2 spread spatially.

The magnetic shield may have a width of, but is not limited to, about 0.01 to 10 μm in a plan view. The magnetic shield may be formed before or after the process for forming the cathode electrode wire 25 and the anode electrode wire 26. Multiple magnetic shields may be arranged parallel to one another.

The electromagnetic wave shield 70 may include a magnetic shielding layer stacked on at least a part of its surface. This structure more effectively weakens the electromagnetic wave EM1 and the electromagnetic wave EM2, thus further reducing electromagnetic interference resulting from the electromagnetic waves EM1 and EM2. The magnetic shielding layer may be stacked on a portion with an area of 10% or more of the uncovered surface of the electromagnetic wave shield 70. However, the range is not limited to this example.

In the first subpixel, the first drive current IA1 through the first light emitter 6A1 and the first drive current IA2 through the first light emitter 6A2 flow in opposite directions. Thus, the electromagnetic wave EM1 induced by the first drive current IA1 has a phase opposite to the phase of the electromagnetic wave EM1 induced by the first drive current IA2. The period in which the first drive current IA1 flows and the period in which the first drive current IA2 flows are simultaneous with and overlap each other. This weakens the electromagnetic waves EM1, thus reducing electromagnetic interference. The second subpixel and the third subpixel each have the same or a similar structure.

Each of the switching transistors TR1 to TR3 includes a gate electrode, and switches, based on the voltage applied to the gate electrode, conduction (on-state) and non-conduction (off-state) between a source electrode and a drain electrode. In the example described below, each of the switching transistors TR1 to TR3 is a TFT including a semiconductor film (channel), the gate electrode, the source electrode, and the drain electrode. The switching transistors TR1 to TR11 may be n-channel TFTs or p-channel TFTs.

The multiple switching transistors TR1 to TR3 form a connection switcher. The operation of the first switching transistor TR1, the second switching transistor TR2, the third switching transistor TR3, and the first light emitters 6A1 and 6A2 included in the first subpixel in an example will now be described with reference to Table 1 below.

TABLE 1

| First | Second | Third | First light | First light |
|---|---|---|---|---|
| switching | switching | switching | emitter | emitter |
| transistor TR1 | transistor TR2 | transistor TR | 6A1 | 6A2 |
| Conductive | Non- | Conductive | Parallel | Parallel |
| | conductive | | emission | emission |
| Non- | Conductive | Non- | Series | Series |
| conductive | | conductive | emission | emission |
| Non- | Non- | Conductive | Non- | Emission |
| conductive | conductive | | emission | |
| Conductive | Non- | Non- | Emission | Non- |
| | conductive | conductive | | emission |

When the first switching transistor TR1 is conductive, the second switching transistor TR2 non-conductive, and the third switching transistor TR3 conductive, the first light emitter 6A1 and the first light emitter 6A2 are connected in parallel and both emit light. This state is referred to as parallel emission. The parallel emission by the first light emitter 6A1 and the second light emitter 6A2 reduces electromagnetic interference with the components and equipment surrounding the display device, and also reduces electromagnetic influence on living bodies such as humans.

When the first switching transistor TR1 is non-conductive, the second switching transistor TR2 conductive, and the third switching transistor TR3 non-conductive, the first light emitter 6A1 and the second light emitter 6A2 are connected in series and both emit light. This state is referred to as series emission. The series emission maximizes the luminance of a display panel and reduces power consumption for achieving the same luminance as in the parallel emission.

When the first switching transistor TR1 is non-conductive, the second switching transistor TR2 non-conductive, and the third switching transistor TR3 conductive, the first light emitter 6A1 emits no light, and the second light emitter 6A2 emits light. When the first switching transistor TR1 is conductive, the second switching transistor TR2 non-conductive, and the third switching transistor TR3 non-conductive, the first light emitter 6A1 emits light, and the second light emitter 6A2 emits no light.

For the second subpixel, the emission or non-emission state of the second light emitters 6B1 and 6B2 can be controlled in the same manner as or a similar manner to the above control. For the third subpixel, the emission or non-emission state of the third light emitters 6C1 and 6C2 can be controlled in the same manner as or a similar manner to the above control.

The first light emitter 6A1 may be in the emission state and the first light emitter 6A2 in the non-emission state in the first subpixel, whereas the second light emitter 6B1 may be in the non-emission state and the second light emitter 6A2 in the emission state in the second subpixel. In this case, the first drive current IA1 and the second drive current IB2 flow in opposite directions. The electromagnetic wave EM1 and the electromagnetic wave EM2 thus cancel each other. The first light emitter 6A1 may be in the non-emission state and the first light emitter 6A2 in the emission state in the first subpixel, whereas the second light emitter 6B1 may be in the emission state and the second light emitter 6A2 in the non-emission state in the second subpixel. In this case as well, the electromagnetic wave EM1 and the electromagnetic wave EM2 cancel each other. The second subpixel and the third subpixel may each be controlled in the same or a similar manner.

Two light emitters 6 in the emission state may be set to be at a distance less than or equal to the maximum distance Lmax at which the magnetic fields generated by the respective drive currents interact with each other. This structure effectively reduces electromagnetic interference. The two light emitters 6 in the emission state may be selected as appropriate in each pixel.

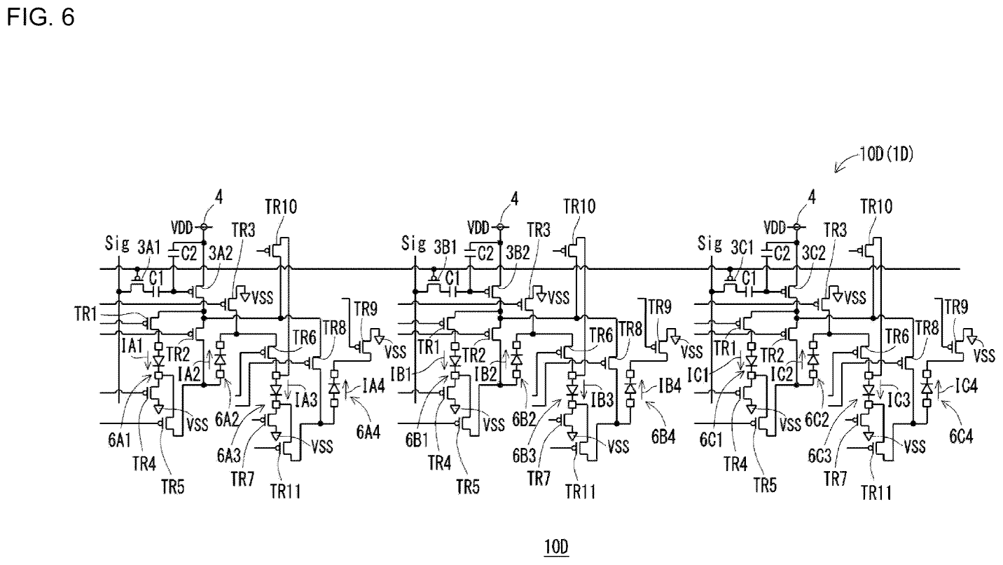

FIG. 6 is a circuit diagram of the display device 10D according to another embodiment of the present disclosure. The same reference numerals denote the components corresponding to those in the embodiments described above. FIG. 6 is a circuit diagram of one pixel. Each pixel in the display device 10D includes a first subpixel, a second subpixel, and a third subpixel. The first subpixel includes four first light emitters 6A1 to 6A4. A drive current IA1 through the first light emitter 6A1 and a drive current IA2 through the first light emitter 6A2 flow in opposite directions. The electromagnetic wave EM1 induced by the drive current IA1 has a phase opposite to the phase of the electromagnetic wave EM1 induced by the drive current IA2. The period in which the drive current IA1 flows and the period in which the drive current IA2 flows are simultaneous with and overlap each other. The electromagnetic wave EM1 induced by the drive current IA1 and the electromagnetic wave EM1 induced by the drive current IA2 thus cancel each other. A drive current IA3 through the first light emitter 6A3 and a drive current IA4 through the first light emitter 6A4 flow in opposite directions. The electromagnetic wave EM1 induced by the drive current IA3 have a phase opposite to the phase of the electromagnetic wave EM1 induced by the drive current IA4. The period in which the drive current IA3 flows and the period in which the drive current IA4 flows are simultaneous with and overlap each other. The electromagnetic wave EM1 induced by the drive current IA3 and the electromagnetic wave EM1 induced by the drive current IA4 thus cancel each other.

The second subpixel includes four second light emitters 6B1 to 6B4. The four second light emitters 6B1 to 6B4 included in the second subpixel can be controlled in the same manner as or a similar manner to the control in the first subpixel. The third subpixel includes four second light emitters 6C1 to 6C4. The four second light emitters 6C1 to 6C4 included in the third subpixel can be controlled in the same manner as or a similar manner to the control in the first subpixel. The above structure reduces electromagnetic interference when one pixel includes more light emitters (12 light emitters in the example in FIG. 6).

The first subpixel includes multiple switching transistors TR1 to TR11 for switching the emission state and the non-emission state of each of the first light emitters 6A1 to 6A4. The second subpixel and the third subpixel each have the same or a similar structure. The switching transistors TR1 to TR11 are TFTs. Each of the switching transistors TR1 to TR11 may be an n-channel TFT or a p-channel TFT.

The multiple switching transistors TR1 to TR11 form a connection switcher. The operation of the switching transistors TR1 to TR11 and the first light emitters 6A1 to 6A4 included in the first subpixel in an example will now be described with reference to Table 2 below.

TABLE 2

| | | | | | | | |
|---|---|---|---|---|---|---|---|
| First | Conductive | Conductive | Conductive | Conductive | Non- | Non- | Conductive |
| switching | | | | | conductive | conductive | |
| transistor | | | | | | | |
| TR1 | | | | | | | |
| First | Conductive | Conductive | Non- | Conductive | Non- | Non- | Non- |
| switching | | | conductive | | conductive | conductive | conductive |
| transistor | | | | | | | |
| TR2 | | | | | | | |
| First | Conductive | Non- | Conductive | Conductive | Conductive | Conductive | Conductive |
| switching | | conductive | | | | | |
| transistor | | | | | | | |
| TR3 | | | | | | | |
| First | Conductive | Non- | Non- | Conductive | Conductive | Conductive | Non- |
| switching | | conductive | conductive | | | | conductive |
| transistor | | | | | | | |
| TR4 | | | | | | | |
| First | Non- | Conductive | Conductive | Non- | Non- | Non- | Conductive |
| switching | conductive | | | conductive | conductive | conductive | |
| transistor | | | | | | | |
| TR5 | | | | | | | |
| First | Non- | Conductive | Non- | Non- | Non- | Non- | Non- |
| switching | conductive | | conductive | conductive | conductive | conductive | conductive |
| transistor | | | | | | | |
| TR6 | | | | | | | |
| First | Conductive | Non- | Conductive | Conductive | Non- | Non- | Non- |
| switching | | conductive | | | conductive | conductive | conductive |
| transistor | | | | | | | |
| TR7 | | | | | | | |
| First | Conductive | Non- | Non- | Non- | Non- | Conductive | Non- |
| switching | | conductive | conductive | conductive | conductive | | conductive |
| transistor | | | | | | | |
| TR8 | | | | | | | |
| First | Conductive | Conductive | Conductive | Conductive | Conductive | Conductive | Conductive |
| switching | | | | | | | |
| transistor | | | | | | | |
| TR9 | | | | | | | |
| First | Conductive | Non- | Non- | Non- | Conductive | Conductive | Conductive |
| switching | | conductive | conductive | conductive | | | |
| transistor | | | | | | | |
| TR10 | | | | | | | |
| First | Non- | Conductive | Non- | Non- | Conductive | Conductive | Conductive |
| switching | conductive | | conductive | conductive | | | |
| transistor | | | | | | | |
| TR11 | | | | | | | |
| First | Parallel | Series | Series | Parallel | Non- | Non- | Series |
| light | emission | emission | emission | emission | emission | emission | emission |
| emitter | | | | | state | | |
| 6A1 | | | | | | | |
| First | Parallel | Series | Series | Parallel | Non- | Non- | Series |
| light | emission | emission | emission | emission | emission | emission | emission |
| emitter | | | | | state | | |
| 6A2 | | | | | | | |
| First | Parallel | Series | Non- | Non- | Series | Parallel | Series |
| light | emission | emission | emission | emission | emission | emission | emission |
| emitter | | | | | | | |
| 6A3 | | | | | | | |
| First | Parallel | Series | Non- | Non- | Series | Parallel | Series |
| light | emission | emission | emission | emission | emission | emission | emission |
| emitter | | | | | | | |
| 6A4 | | | | | | | |

The first light emitters 6A1 to 6A4 may perform parallel emission that reduces electromagnetic interference with the components and equipment surrounding the display device, and also reduces electromagnetic influence on living bodies such as humans. For example, the display device 10D according to the present embodiment is suitable for a display device in, for example, a smartphone that displays a standby screen for a long period. The first light emitters 6A1 to 6A4 may perform series emission that maximizes the luminance of the display panel and reduces power consumption for achieving the same luminance as in the parallel light emission. The four first light emitters 6A1 to 6A4 each have a current of the same value, maximizing the cancellation effect of the electromagnetic fields adjacent to the four first light emitters 6A1 to 6A4. The four first light emitters 6A1 to 6A4 may thus be suitable for displaying, for example, an image on a smartphone during a call. The display device 10D can selectively cause each of the first light emitters 6A1 to 6A4 to perform the series emission or the parallel emission, thus smoothing variations in chromaticity. Further, any subpixel including a defective light emitter with a mounting fault or another cause can be switched to an electrically non-emission state. A pixel or some of the subpixels in a pixel can also be switched to the non-emission state.

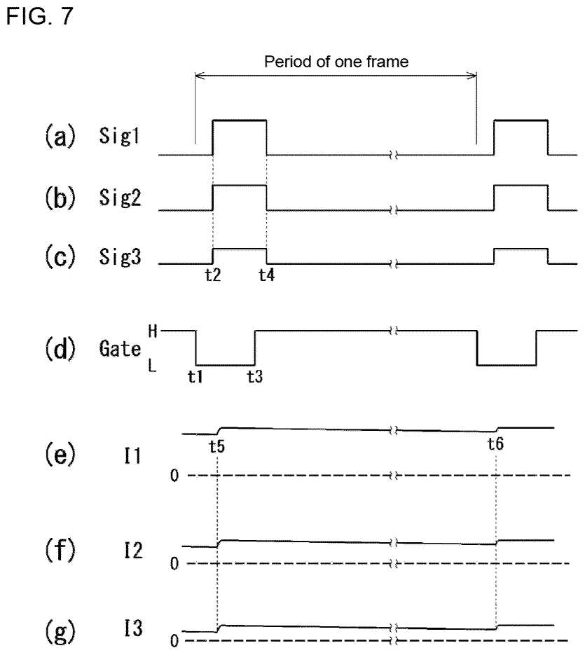

FIG. 7 is a timing chart describing the operation of the light-emitting device 1 according to the embodiment illustrated in FIG. 2, illustrating (a) an emission control signal Sig1, (b) an emission control signal Sig2, (c) an emission control signal Sig3, (d) a gate signal Gate, (e) a drive current I1, (f) a drive current I2, and (g) a drive current I3. During a period from time t1 to time t3, the gate signal Gate input into the gate electrode of each of the first, second, and third switch transistors 3A1, 3B1, and 3C1 changes from a high level to a low level. This turns on the first, second, and third switch transistors 3A1, 3B1, and 3C1. In this state, the emission control signals Sig1, Sig2, and Sig3 input from the respective source signal lines are input from the respective drain electrodes of the first, second, and third switch transistors 3A1, 3B1, and 3C1 into the respective gate electrodes of the first, second, and third drive transistors 3A2, 3B2, and 3C2 during a period from time t2 to time t4. Drive signals corresponding to the respective gate voltages of the first, second, and third light emitters 6A, 6B, and 6C are then output from the first, second, and third drive transistors 3A2, 3B2, and 3C2 to the respective first, second, and third light emitters 6A, 6B, and 6C.

The first, second, and third light emitters 6A, 6B, and 6C have first, second, and third drive currents I1, I2, and I3 corresponding to the voltage levels of the respective emission control signals Sig1, Sig2, and Sig3 at time t5. At time t6 (corresponding to the next time t5), the subsequent gate signal Gate is subsequently input into the gate electrode of each of the first, second, and third switch transistors 3A1, 3B1, and 3C1, and the emission control signals Sig1, Sig2, and Sig3 are input from the respective source signal lines into the respective source electrodes. The drive currents I1, I2, and I3 flow through the respective first, second, and third light emitters 6A, 6B, and 6C until the next time t6, and the emission states of the first, second, and third light emitters 6A, 6B, and 6C are maintained. As described above, the electromagnetic wave EM1 generated by the drive current I1 has a phase opposite to the phases of the electromagnetic wave EM2 generated by the drive current I2 and the electromagnetic wave EM3 generated by the drive current I3. The electromagnetic waves EM1 to EM3 thus at least partially cancel one another, reducing electromagnetic interference.

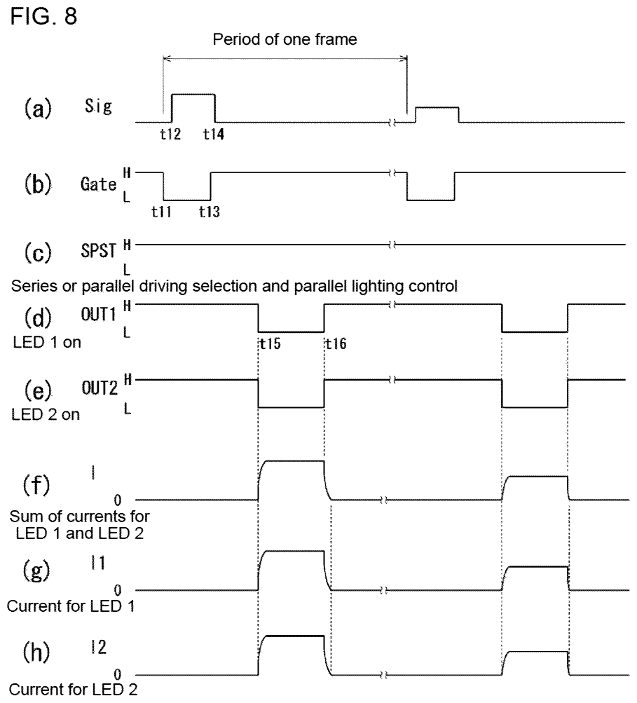

FIG. 8 is a timing chart describing the operation of the first subpixel in the display device 10C according to the embodiment illustrated in FIG. 5 during parallel driving. Each of the second and the third subpixels also operates in the same manner as or a similar manner to the first subpixel, and will not be described. FIG. 8 illustrates (a) an emission control signal Sig, (b) a gate signal Gate, (c) a selection signal SPST for selecting series driving or parallel driving, (d) a lighting control signal OUT1 for controlling lighting of an LED 1 (first light emitter 6A2), (e) a lighting control signal OUT2 for controlling lighting of an LED 2 (first light emitter 6A1), (f) a current I that is a sum of drive currents I1 and I2, (g) a drive current I1, and (h) a drive current I2.

The signals Sig, Gate, SPST, OUT1, OUT2, I, I1, and I2 are input into each pixel from, for example, a drive in a drive element such as a drive circuit (driver), an IC, or other drive elements located on a frame of the substrate 7. The drive element may be mounted on a circuit board such as a flexible printed circuit board (FPC). The circuit board may include a connection terminal electrically connected to a connection electrode of the substrate 7 through a conductive connector such as an anisotropic conductive film (ACF).

For the gate voltage of each of the TR1, TR2, and TR3, the selection signal SPST (high/low), the lighting control signal OUT1, and the lighting control signal OUT2 are controlled to select series emission (series driving) or parallel emission (parallel driving). In the parallel driving illustrated in FIG. 8, for example, in response to a selection signal SPST that is a high-signal (off-signal) input into the gate electrode of the drive transistor TR2, the parallel driving is selected. In response to a lighting control signal OUT1 that is a low-signal (on-signal) input into the gate electrode of the drive transistor TR3, the drive current I1 (corresponding to the IA2 in FIG. 5) is supplied to the LED 1 (first light emitter 6A2) to turn on the LED 1. In response to a lighting control signal OUT2 that is a low-signal (on-signal) input into the gate electrode of the drive transistor TR1, the drive current I2 (corresponding to the IA1 in FIG. 5) is supplied to the LED 2 (first light emitter 6A1) to turn on the LED 2.

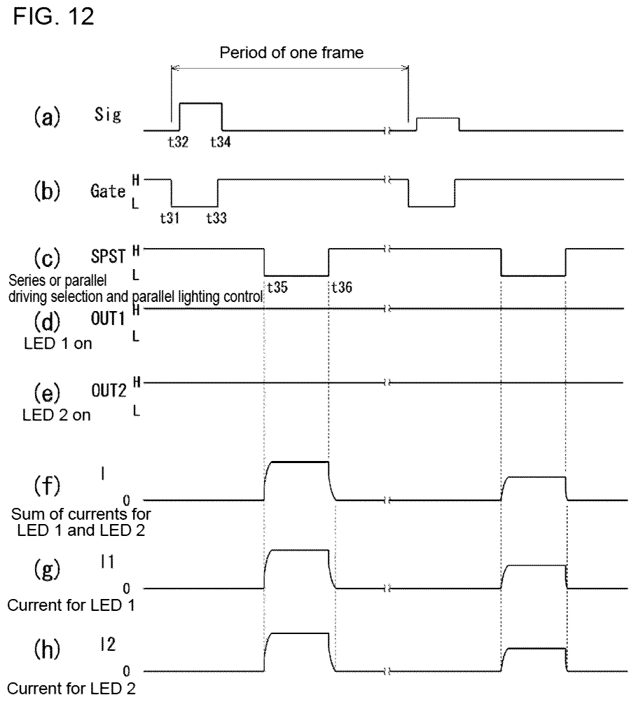

In the series driving illustrated in FIG. 12, for example, in response to a selection signal SPST that is a low-signal (on-signal) input into the gate electrode of the drive transistor TR2, the series driving is selected. In response to a lighting control signal OUT1 that is a high-signal (off-signal) input into the gate electrode of the drive transistor TR3, the drive current I1 is supplied to the LED 1 (first light emitter 6A2) to turn on the LED 1. In response to a lighting control signal OUT2 that is a high-signal (off-signal) input into the gate electrode of the drive transistor TR1, the drive current I2 is supplied to the LED 2 (first light emitter 6A1) to turn on the LED 2.

The timing chart during the parallel driving in FIG. 8 will now be described. The first switch transistor 3A1 is turned on during a period from time t11 to time t13, with the gate signal Gate input into the gate electrode of the first switch transistor 3A1 being changed to a low level. An emission control signal Sig from the corresponding source signal line is input from the drain electrode of the first switch transistor 3A1 into the gate electrode of the first drive transistor 3A2 during a period from time t12 to time t14. The drive current I1 is output from the first drive transistor 3A2 to the LED 1 (first light emitter 6A2) and the drive current I2 is output from the first drive transistor 3A2 to the LED 2 (first light emitter 6A1) during a period from time t15 to time t16 (during the lighting control signal OUT1 being at a low level). Thus, the drive current I1 flows through the LED 1 (first light emitter 6A2), and the drive current I2 flows through the LED 2 (first light emitter 6A1) during the period from time t15 to time t16.

The lighting period of the first light emitter 6A1 and the lighting period of the first light emitter 6A2 are simultaneous with and overlap each other, and thus the drive current I flows through the first light emitters 6A1 and 6A2. While the drive current I is flowing, the electromagnetic waves EM1 are generated. The electromagnetic wave EM1 generated by the drive current IA1 through the first light emitter 6A1 has a phase opposite to the phase of the electromagnetic wave EM1 generated by the drive current IA2 through the first light emitter 6A2. The electromagnetic waves EM1 thus cancel each other and are weakened. This structure thus reduces electromagnetic interference.

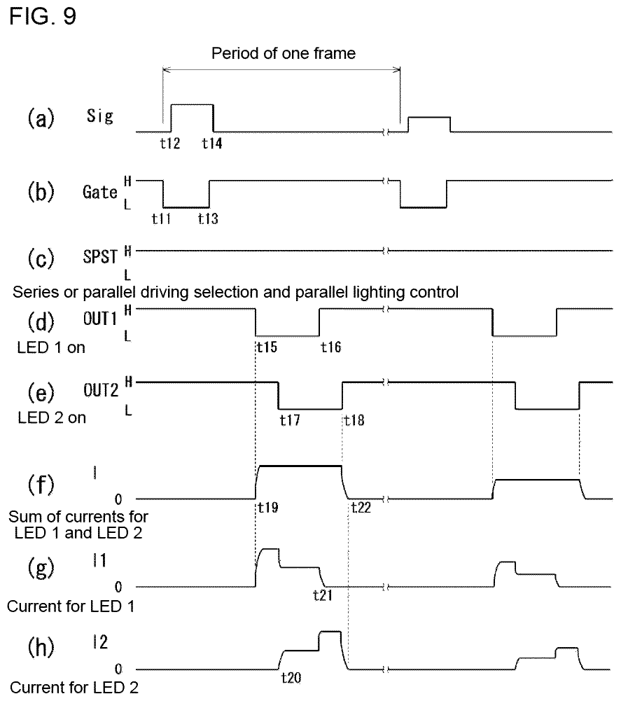

As in the parallel driving described in the timing chart in FIG. 9, the time to turn on the drive transistor TR1 and the time to turn on the drive transistor TR3 may be shifted to shift the period in which the drive current IA1 flows and the period in which the drive current IA2 flows. In this case, the lighting period of the first light emitter 6A1 and the lighting period of the first light emitter 6A2 partially overlap each other. For example, when the first light emitters 6A1 and 6A2 emit light of the same color, the entire emission period can be extended. The first light emitter 6A1 and the first light emitter 6A2 each have a lighting period shorter than the entire emission period and thus have a longer service life.

The first drive transistor 3A2 outputs the drive current I1 to the LED 1 (first light emitter 6A2) during a period from time t15 to time t16 (during the lighting control signal OUT1 being at a low level). The LED 1 emits light during a period from time t19 (t19=t15) to time t21 (t21˜ t16). The first drive transistor 3A2 also outputs the drive current I2 to the LED 2 (first light emitter 6A1) during a period from time t17 to time t18 (during the lighting control signal OUT2 being at a low level). The LED 2 emits light during a period from time t20 (t20=t17) to time t22 (t22˜ t18). The LED 1 and the LED 2 thus emit light during a period from time t15 to time t18. As illustrated in FIG. 9, the drive current I, which is a combined current of the drive current I1 and the drive current I2, may be substantially constant during the period from time t15 to time t18, and the light intensities (luminance) of the LED 1 and the LED 2 may be substantially constant. More specifically, the luminance of the LED 1 during the period in which the LED 1 alone emits light, the luminance of the LED 1 and the LED 2 during the period in which the LED 1 and the LED 2 emit light, and the luminance of the LED 2 during the period in which the LED 2 alone emits light may be substantially the same. This structure reduces fluctuations in luminance during the period in which the first subpixel emits light. To achieve the above structure, for example, the drive current I1 may have, during a period from time t17 to time t21, a current level being about half the current level during a period from time t15 to time t17. The drive current I2 may have, during a period from time t20 to time t16, a current level being about half the current level during a period from time t16 to time t22.

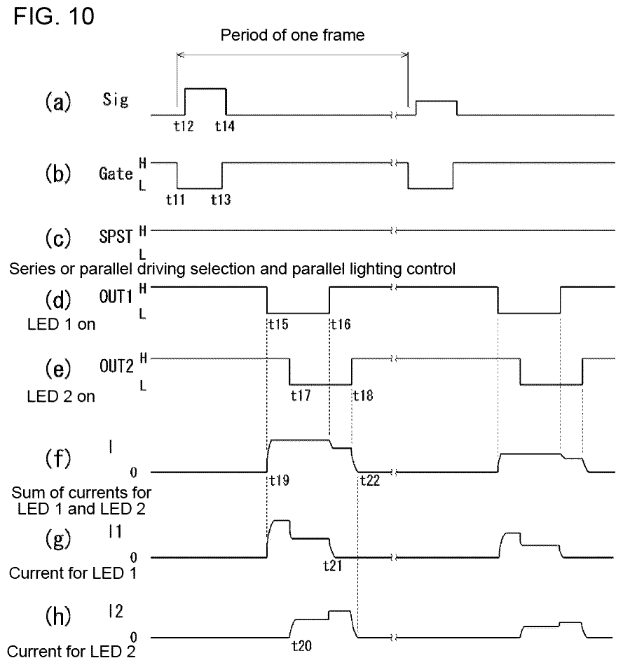

As illustrated in the timing chart of FIG. 10, the drive current I may have a constant current level during a period from time t15 to time t16, and may have a lower current level during a period from time t16 to time t18 than the current level during the period from time t15 to time t16. In this structure, fluctuations in the luminance of the first subpixel are less visible due to the afterimage effect of the viewer's eyes. This structure reduces the levels of the electromagnetic waves EM1 generated while the drive current I is flowing, thus further reducing electromagnetic interference. The current level during the period from time t16 to time t18 may be about 50% or more of the current level during the period from time t15 to time t16, or may be about 50 to 90%, or about 70 to 90%. The period from time t15 to time t16 may be 50% or more of the period from time t15 to time t18, or may be about 50 to 90%, or about 70 to 90%. The period from time t16 to time t18 may be shorter than the period from time t15 to time t16. In this structure, fluctuations in the luminance of the first subpixel are still less visible due to the afterimage effect of the viewer's eyes.

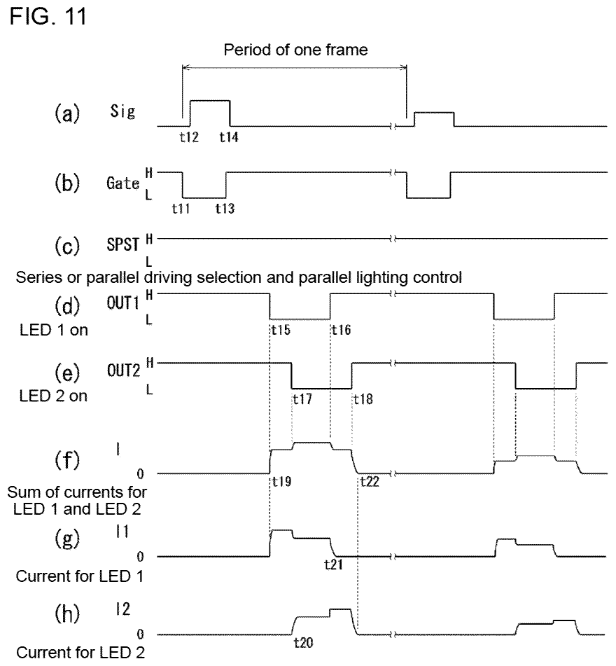

As illustrated in the timing chart in FIG. 11, the drive current I may have the highest current level (luminance) during a period from time t17 to time t16. In other words, the current level may be the highest during the period in which the LED 1 and the LED 2 emit light. This is because fluctuations in the luminance of the first subpixel are less visible due to the afterimage effect of the viewer's eyes although the drive current I is not substantially constant across the entire period from time t15 to time t18. This structure further reduces the levels of the electromagnetic waves EM1 generated while the drive current I is flowing, thus further reducing electromagnetic interference. The period from time t17 to time t16 may be 50% or more of the period from time t15 to time t18, or may be about 50 to 90%, or about 50 to 70%.

The drive current I may have the highest current level during the period from time t17 to time t16, the second highest current level during a period from time t15 to time t17, and the lowest current level during a period from time t16 to time t18. This is because fluctuations in the luminance of the first subpixel are less visible due to the afterimage effect of the viewer's eyes although the luminance during the period from time t16 to time t18 is lowest. This structure further reduces the levels of the electromagnetic waves EM1 generated while the drive current I is flowing, thus further reducing electromagnetic interference.

FIG. 12 is a timing chart describing the operation of the first subpixel in the display device 10C according to the embodiment illustrated in FIG. 5 during series driving. Each of the second subpixel and the third subpixel also operates in the same as or a similar manner to the first subpixel, and will not be described. The first switch transistor 3A1 is turned on when the gate signal Gate provided to the gate electrode of the first switch transistor 3A1 switches from a high level to a low level during a period from time t31 to time t33. An emission control signal Sig from the corresponding source signal line is input from the drain electrode of the first switch transistor 3A1 into the gate electrode of the first drive transistor 3A2 during a period from time t32 to time t34. Thus, the drive current IA1 is output from the first drive transistor 3A2 to the first light emitter 6A1, and the drive current IA2 is output from the first drive transistor 3A2 to the first light emitter 6A2 during a period from time t35 to time t36, which is later than time t34. The electromagnetic wave EM1 generated by the drive current I1 through the first light emitter 6A1 has a phase opposite to the phase of the electromagnetic wave EM1 generated by the drive current I2 through the first light emitter 6A2. The electromagnetic waves EM1 thus cancel each other and are weakened to reduce electromagnetic interference.

In the series driving in FIG. 12, the drive current IA2 and the drive current IA1 flow through a series circuit in this order. This may cause the emission period of the first light emitter 6A2 to be shifted from the emission period of the first light emitter 6A1. In this case, the lighting period of the first light emitter 6A1 and the lighting period of the first light emitter 6A2 partially overlap each other. For example, when the first light emitters 6A1 and 6A2 emit light of the same color, the entire emission period can be extended. The first light emitter 6A1 and the first light emitter 6A2 each have a lighting period shorter than the entire emission period and thus have a longer service life.

In another embodiment of the present disclosure, two light emitters 6 in the emission state may be set to be at a distance less than or equal to the maximum distance Lmax at which the magnetic fields generated by the respective drive currents interact with each other. This structure effectively reduces electromagnetic interference. The two light emitters 6 in the emission state may be selected as appropriate in each pixel.

In one or more embodiments of the present disclosure, the light emitters are self-luminous light emitters such as LEDs, organic electroluminescent (EL) elements, and semiconductor laser elements. The light emitters may be flip-chip connected LED elements, or specifically, transversely mounted chip LED elements. A flip-chip connected LED element has a drive current flowing in a direction parallel to the plane direction of the substrate 7. Thus, the flip-chip connected LED element is likely to have a longer current path than a vertically mounted LED element formed with, for example, a thin film formation method. The flip-chip connected LED element is thus likely to have an electromagnetic wave generated by the drive current and spreading into the surroundings. The light-emitting device and the display device including the flip-chip connected LED element according to one or more embodiments of the present disclosure can effectively reduce electromagnetic interference and electromagnetic influence. The electromagnetic effects on living bodies may cause, for example, fatigue in mild cases, and diseases in severe cases. The structure according to one or more embodiments of the present disclosure is thus useful to reduce health concerns associated with electronic devices.

In one or more embodiments of the present disclosure, the light-emitting device and the display device can reduce electromagnetic interference with, for example, surrounding components and devices, and can reduce electromagnetic influence on living bodies such as humans. The electromagnetic interference is generated when the magnetic field generated by the first drive current flowing through the first light emitter and the electromagnetic wave induced by the magnetic field has a phase aligned with the phase of the electromagnetic wave generated by the second drive current flowing through the second light emitter and the electromagnetic wave induced by the magnetic field. When the period in which the first drive current flows and the period in which the second drive current flows partially overlap each other, the entire emission period of the first light emitter and the second light emitter emitting the same color of light can be extended. The first light emitter and the second light emitter each have a lighting period shorter than the entire emission period and thus have a longer service life.

The light-emitting device according to one or more embodiments of the present disclosure may have the structures (1) to (7) described below.

(1) A light-emitting device, comprising:
a first light emitter; and
a second light emitter,
wherein a first drive current through the first light emitter and a second drive current through the second light emitter flow in opposite directions, and
a period in which the first drive current flows and a period in which the second drive current flows at least partially overlap each other.

(2) The light-emitting device according to (1), wherein
the first light emitter and the second light emitter are at a distance less than or equal to a maximum distance at which a magnetic field generated by the first drive current and a magnetic field generated by the second drive current interact with each other.

(3) The light-emitting device according to (1) or (2), wherein
the first drive current has a same magnitude as the second drive current.

(4) The light-emitting device according to any one of (1) to (3), wherein
the first light emitter is connected to a connection wire including a portion parallel to a portion of a connection wire connected to the second light emitter.

(5) The light-emitting device according to any one of (1) to (4), further comprising:
a connection switcher configured to connect the first light emitter and the second light emitter in series or in parallel.

(6) The light-emitting device according to any one of (1) to (5), further comprising:
an electromagnetic wave shield between the first light emitter and the second light emitter.

(7) The light-emitting device according to (6), wherein
the electromagnetic wave shield is located closer to one of the first light emitter or the second light emitter having a greater drive current when the first drive current and the second drive current have different magnitudes.

The display device according to one or more embodiments of the present disclosure may have the structures (8) to (17) described below.

(8) A display device, comprising:
a pixel;
a first light emitter included in the pixel; and
a second light emitter included in the pixel,
wherein a first drive current through the first light emitter and a second drive current through the second light emitter flow in opposite directions, and
a period in which the first drive current flows and a period in which the second drive current flows at least partially overlap each other.

(9) The display device according to (8), wherein
the first light emitter and the second light emitter are at a distance less than a maximum distance at which a magnetic field generated by the first drive current and a magnetic field generated by the second drive current interact with each other.

(10) The display device according to (8) or (9), wherein
the first drive current has a same magnitude as the second drive current.

(11) The display device according to any one of (8) to (10), wherein
the first light emitter is connected to a connection wire including a portion parallel to a portion of a connection wire connected to the second light emitter.

(12) The display device according to any one of (8) to (11), wherein
the first light emitter and the second light emitter are red light emitters configured to emit red light.

(13) The display device according to any one of (8) to (12), further comprising:
a connection switcher configured to connect the first light emitter and the second light emitter in series or in parallel.

(14) The display device according to any one of (8) to (13), further comprising:
an electromagnetic wave shield between the first light emitter and the second light emitter.

(15) The display device according to (14), wherein
the electromagnetic wave shield is located closer to one of the first light emitter or the second light emitter having a greater drive current when the first drive current and the second drive current have different magnitudes.

(16) The display device according to any one of (8) to (14), further comprising:
a third light emitter included in the pixel,
wherein the first light emitter, the second light emitter, and the third light emitter are arranged in a predetermined direction in an order of the first light emitter, the second light emitter, and the third light emitter,
a third drive current through the third light emitter and the second drive current flow in opposite directions, and
a period in which the first drive current flows, a period in which the second drive current flows, and a period in which the third drive current flows at least partially overlap one another.

(17) The display device according to any one of (8) to (15), further comprising:
a third light emitter included in the pixel; and
a fourth light emitter included in the pixel,
wherein the first light emitter and the second light emitter are adjacent to each other, and
each of the first drive current and the second drive current is greater than a third drive current flowing through the third light emitter, and the each of the first drive current and the second drive current is greater than a fourth drive current flowing through the fourth light emitter.

Although embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### REFERENCE SIGNS

1 light-emitting device
2 insulating substrate
3 transistor
3A1 first switch transistor
3B1 second switch transistor
3C1 third switch transistor
3A2 first drive transistor
3B2 second drive transistor
3C2 third drive transistor
4 first power terminal
5 connection conductor layer
6A, 6A1, 6A2, 6A3, 6A4 first light emitter
6B, 6B1, 6B3, 6B3, 6B4 second light emitter
6C, 6C1, 6C2, 6C3, 6C4 third light emitter
L1 distance
2a first surface (one main surface)
2b second surface (other main surface)
21, 22, 23 insulating layer
24a to 24c internal wire
25 cathode electrode wire
26 anode electrode wire
25a transparent conductive layer
26a transparent conductive layer
7 substrate
7a third surface (one main surface)
7b fourth surface (other main surface)
7c fifth surface (side surface)
31 gate electrode
32 source electrode
33 drain electrode
VDD first power supply voltage
VSS second power supply voltage
61 cathode terminal
62 anode terminal
70 electromagnetic wave shield

1. A light-emitting device, comprising:
a first light emitter; and
a second light emitter,
wherein a first drive current through the first light emitter and a second drive current through the second light emitter flow in opposite directions, and
a period in which the first drive current flows and a period in which the second drive current flows at least partially overlap each other.

2. The light-emitting device according to claim 1, wherein
the first light emitter and the second light emitter are at a distance less than or equal to a maximum distance at which a magnetic field generated by the first drive current and a magnetic field generated by the second drive current interact with each other.

3. The light-emitting device according to claim 1, wherein
the first drive current has a same magnitude as the second drive current.

4. The light-emitting device according to claim 1, wherein
the first light emitter is connected to a connection wire including a portion parallel to a portion of a connection wire connected to the second light emitter.

5. The light-emitting device according to claim 1, further comprising:
a connection switcher configured to connect the first light emitter and the second light emitter in series or in parallel.

6. The light-emitting device according to claim 1, further comprising:
an electromagnetic wave shield between the first light emitter and the second light emitter.

7. The light-emitting device according to claim 6, wherein
the electromagnetic wave shield is located closer to one of the first light emitter or the second light emitter having a greater drive current when the first drive current and the second drive current have different magnitudes.

8. A display device, comprising:
a pixel;
a first light emitter included in the pixel; and
a second light emitter included in the pixel,
wherein a first drive current through the first light emitter and a second drive current through the second light emitter flow in opposite directions, and
a period in which the first drive current flows and a period in which the second drive current flows at least partially overlap each other.

9. The display device according to claim 8, wherein
the first light emitter and the second light emitter are at a distance less than a maximum distance at which a magnetic field generated by the first drive current and a magnetic field generated by the second drive current interact with each other.

10. The display device according to claim 8, wherein
the first drive current has a same magnitude as the second drive current.

11. The display device according to claim 8, wherein
the first light emitter is connected to a connection wire including a portion parallel to a portion of a connection wire connected to the second light emitter.

12. The display device according to claim 8, wherein
the first light emitter and the second light emitter are red light emitters configured to emit red light.

13. The display device according to claim 8, further comprising:
a connection switcher configured to connect the first light emitter and the second light emitter in series or in parallel.

14. The display device according to claim 8, further comprising:
an electromagnetic wave shield between the first light emitter and the second light emitter.

15. The display device according to claim 14, wherein
the electromagnetic wave shield is located closer to one of the first light emitter or the second light emitter having a greater drive current when the first drive current and the second drive current have different magnitudes.

16. The display device according to claim 8, further comprising:
a third light emitter included in the pixel,
wherein the first light emitter, the second light emitter, and the third light emitter are arranged in a predetermined direction in an order of the first light emitter, the second light emitter, and the third light emitter,
a third drive current through the third light emitter and the second drive current flow in opposite directions, and
a period in which the first drive current flows, a period in which the second drive current flows, and a period in which the third drive current flows at least partially overlap one another.

17. The display device according to claim 8, further comprising:
a third light emitter included in the pixel; and
a fourth light emitter included in the pixel,
wherein the first light emitter and the second light emitter are adjacent to each other, and
each of the first drive current and the second drive current is greater than a third drive current flowing through the third light emitter, and the each of the first drive current and the second drive current is greater than a fourth drive current flowing through the fourth light emitter.
